(19) United States
(12) Patent Application Publication
(10) Pub. No.: US 2026/0321550 A1
(43) Pub. Date: Oct. 15, 2026

(54) SHOWERHEAD OPTIMIZATION FOR REDUCING SHOWERHEAD IMPEDANCE IN SEMICONDUCTOR FABRICATION EQUIPMENT

(71) Applicant: Lam Research Corporation, Fremont, CA (US)

(72) Inventors: Yogesh Babbar, Hillsboro, OR (US); Weifeng Cheng, Portland, OR (US); David French, Fort Myers, FL (US); Yue Zhang, Lake Oswego, OR (US); Aleksey V. Altecor, Newberg, OR (US)

(21) Appl. No.: 19/486,247

(22) PCT Filed: May 20, 2024
(86) PCT No.: PCT/US2024/030240

§ 371 Date: Nov. 20, 2025

Related U.S. Application Data
(60) Provisional application No. 63/503,654, filed on May 22, 2023.

(51) Int. Cl. H01J 37/32; C23C 16/455

(52) U.S. Cl. CPC H01J 37/32568; C23C 16/45565; H01J 37/3244; H01J 37/3255; C23C 16/45536; H01J 2237/3321

(57) ABSTRACT

Apparatuses and methods are provided herein. In some embodiments, a reactance control device for a showerhead in a processing chamber comprises a bottom rim configured to contact at least a portion of a top surface of a showerhead. The reactance control device may include a body surface with an inner connective rim and an outer perimeter connected to the bottom rim via a side wall, a diameter of the inner connective rim is smaller than the outer perimeter of the body surface, wherein the inner connective rim defines a through hole configured to accommodate a portion of a shaft of the showerhead, and the inner connective rim is further configured to engage a mounting device arranged approximate to the shaft portion of the showerhead in order to secure the reactance control device to the showerhead.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Plasma-based operations, such as plasma-enhanced chemical vapor deposition (PECVD), atomic layer deposition (ALD), atomic layer etching (ALE), or the like are often conducted in a plasma reactor that includes two electrodes that are configured to sustain a plasma in the region between the electrodes. The plasma may be ignited and/or sustained when an RF signal is provided to a powered electrode of the two electrodes.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Disclosed herein are systems, apparatuses, and methods for modulation of station impedances during plasma operations.

In some embodiments, a reactance control device for a showerhead in a processing chamber comprises a bottom rim configured to contact at least a portion of a top surface of a showerhead. The reactance control device may include a body surface with an inner connective rim and an outer perimeter connected to the bottom rim via a side wall, a diameter of the inner connective rim is smaller than the outer perimeter of the body surface, wherein the inner connective rim defines a through hole configured to accommodate a portion of a shaft of the showerhead, and the inner connective rim is further configured to engage a mounting device arranged approximate to the shaft portion of the showerhead in order to secure the reactance control device to the showerhead.

In some examples, the body surface is configured to fill at least a portion of a station of the processing chamber between the top surface of the showerhead and a top wall of the station, the body surface comprising a conductive material and configured to support electromagnetic coupling when the showerhead is powered by an RF source. In some examples, the side wall defines a height of the reactance control device, and the height of the reactance control device is less than a distance between the top surface of the showerhead and the top wall of the station.

In some examples, the reactance control device comprises one or more subparts and each of the one or more subparts defines a portion of the inner connective rim.

In some examples, a top portion of the body surface is flat.

In some examples, a top portion of the body surface is at least partially sloped.

In some examples, the body surface forms a convex shape, and wherein an inner region formed by the convex shape is not filled.

In some examples, the conductive material comprises Aluminum.

In some examples, a perimeter of the bottom rim is within a range of about 30 inches to 50 inches.

In some examples, a range of about 40% to 60% of the bottom rim is configured to remain in contact with the at least the portion of the top surface of the showerhead when the reactance control device undergoes thermal expansion.

In some examples, the mounting device is a collar configured to clamp the reactance control device. In some examples, the collar is made of a material that comprises Inconel.

In some examples, the reactance control device is configured to reduce an inductance associated with the showerhead by at least about half relative to the inductance associated with the showerhead when not in contact with the reactance control device.

In some examples, the reactance control device is configured to reduce an inductance associated with the showerhead to less than about 30 nH.

In accordance with some embodiments, a showerhead apparatus is provided, comprising a showerhead, and a reactance control device connected to a portion of a shaft of the showerhead. The reactance control device may comprise: a bottom rim configured to contact at least a portion of a top surface of the showerhead; and a body surface with an inner connective rim and an outer perimeter connected to the bottom rim via a side wall, a diameter of the inner connective rim is smaller than the outer perimeter of the body surface, wherein the inner connective rim defines a through hole configured to accommodate a portion of a shaft of the showerhead, and the inner connective rim is further configured to engage a mounting device arranged approximate to the shaft portion of the showerhead in order to secure the reactance control device to the showerhead.

In some examples, the showerhead reactance control device is clamped to the showerhead.

In some examples, a top portion of the body surface is flat.

In some examples, a top portion of the body surface is at least partially sloped.

In some examples, the body surface forms a convex shape, and wherein an inner region formed by the convex shape is not filled.

In some examples, the conductive material comprises Aluminum.

In some examples, the showerhead reactance control device is configured to reduce an inductance associated with the showerhead by at least about half relative to the inductance associated with the showerhead when not in contact with the reactance control device.

In some examples, the showerhead reactance control device is configured to reduce an inductance associated with the showerhead to less than about 30 nH.

In some examples, the showerhead is disposed in a station of a multi-station chamber, the multi-station chamber comprising at least two or more stations.

In accordance with some embodiments, a method for mounting a reactance control device to a showerhead in a processing chamber is provided. The method may involve aligning the reactance control device with a mounting device arranged approximate to a shaft portion of the showerhead, wherein the reactance control device comprises: a bottom rim configured to contact at least a portion of a top surface of the showerhead; and a body surface with an inner connective rim and an outer parameter connected to the bottom rim, a diameter of the inner connective rim is smaller than the outer parameter of the body surface, wherein the inner connective rim defines a through hole configured to engage the mounting device arranged approximate to the shaft portion of the showerhead. The method may further involve securing the reactance control device to the showerhead via the mounting device, wherein at least a portion of the bottom rim is contacting at least a portion of the top surface of the showerhead when secured.

In some examples, the method further involves installing the showerhead to the processing station.

In some examples, the reactance control device comprises two or more parts, the two or more parts each defines a portion of the inner connective rim and wherein securing the reactance control device to the showerhead comprises connection of the two or more parts of the reactance control device to the mounting device.

According to some embodiments, a showerhead is disclosed herein. The showerhead may comprise a bottom portion comprising one or more ports configured to distribute process gases. The showerhead may comprise a shaft configured to affix the showerhead to a top wall of a process station. The showerhead may comprise a top portion comprising a conductive material, wherein the top portion surrounds at least a bottom portion of the shaft such that the top portion is configured to fill at least a portion of a gap between a top plate of the showerhead and the top wall of the process station.

### BRIEF DESCRIPTION OF THE DRAWINGS

FIG. 1 is a schematic diagram of an example apparatus in accordance with some embodiments.

FIG. 2 is a schematic diagram that represents components of an apparatus configured for plasma operations as equivalent circuit elements in accordance with some embodiments.

FIGS. 3A,3B, and 3C illustrate example configurations of showerhead reactance control devices in accordance with some embodiments.

FIGS. 4A and 4B illustrate example shapes of showerhead reactance control devices in accordance with some embodiments.

FIGS. 5A and 5B depict a relationship between reactance control device dimensions and showerhead impedance in accordance with some embodiments.

FIG. 6 is a flowchart of an example process for modifying a showerhead impedance or inductance via a showerhead reactance control device in accordance with some embodiments.

FIG. 7 is a flowchart of an example process for installing a showerhead reactance control device in accordance with some embodiments.

### DETAILED DESCRIPTION

Plasma-based operations, such as plasma-enhanced chemical vapor deposition (PECVD), atomic layer deposition (ALD), atomic layer etching (ALE), or the like are often conducted in a plasma reactor that includes two electrodes that are configured to sustain a plasma in the region between the electrodes. The plasma may be ignited and/or sustained when an RF signal is provided to a powered electrode of the two electrodes. An unpowered electrode of the two electrodes, affixed to a wall of the plasma reactor, may be effectively DC grounded at relatively low RF frequencies. However, at higher RF frequencies, the unpowered electrode may develop a voltage relative to the walls of the plasma reactor. This voltage may have detrimental effects on the plasma within the reactor, such as causing parasitic plasma in regions of the reactor other than the region between the two electrodes. The detrimental effects on the plasma may create unpredictable and/or adverse conditions for, e.g., semiconductor fabrication operations, such as non-uniformity in deposition layers, non-uniformity in etched layers, etc.

Disclosed herein are reactance control devices that may be configured to be attached to or otherwise in contact with a showerhead of a station, e.g., when the showerhead of the station is an unpowered electrode. The reactance control device may be made of a conductive material that conducts RF signal. The reactance control device may reduce a gap between a top portion of the showerhead and a top wall of the station and/or a top plate of the showerhead, thereby reducing an inductance of the showerhead, and therefore a reactance and an impedance associated with the showerhead. In other words, the reactance control device may effectively fill a portion of the region between a top portion of the showerhead and the top wall of the station or the top plate of the showerhead with an RF conductive material. By reducing the inductance, reactance, or impedance of the showerhead, parasitic plasma may be reduced.

The reactance control device may have a shape that has an inner diameter configured to receive the stem of the showerhead. The reactance control device may have a bottom rim configured to contact at least a portion of a top surface of the showerhead. The reactance control device may have a body surface configured to fill at least a portion of the station between the top surface of the showerhead and the top wall of the station or the top plate of the showerhead. The reactance control device may be made of a conductive material that is resistant to various chemical reactions that may occur in the station, such as Aluminum or an Aluminum alloy. The reactance control device may be clamped or bolted to a portion of the showerhead, e.g., via a collar. In some embodiments, the reactance control device may be affixed to a portion of the showerhead via a friction based retention device, such as an RF gasket. In some embodiments, the reactance control device may have an inverted bowl shape such that the interior portion of the reactance control device is empty. In some embodiments, rather than being formed substantially of a sheet of metal, the body surface and/or the top surface of the reactance control device may be a metal mesh. A reactance control device may be an integral piece, or may be composed of two or more parts.

The reactance control device may include a bottom rim configured to contact at least a portion of a top surface of a showerhead. The reactance control device may include a body surface with an inner connective rim and an outer perimeter connected to the bottom rim via a side wall. The diameter of the inner connective rim may be smaller than the outer perimeter of the body surface. The inner connective rim may define a through hole which may be configured to accommodate a portion of a shaft of the showerhead. The reactance control device may be secured to at least a portion of the shaft of the showerhead via a mounting device. In some embodiments, the inner connective rim of the reactance control device may be configured to engage the mounting device. In some embodiments, the mounting device may be arranged approximate to the shaft portion of the showerhead. For example, the mounting device may include a collar that clamps around the shaft portion of the showerhead. In some embodiments, the mounting device may be bolted to the shaft portion of the showerhead. In some embodiments, the mounting device may be a feature on the showerhead shaft, or alternatively, may be a separate component.

Note that, in some embodiments, rather than having a reactance control device that is affixed to a showerhead, a showerhead may be manufactured to have a shape that corresponds to a showerhead and the reactance control device as one component. In other words, it should be understood that a modified showerhead shape is contemplated in which at least a portion of the top plate of the showerhead extends upwards to fill a gap toward a top portion of the station.

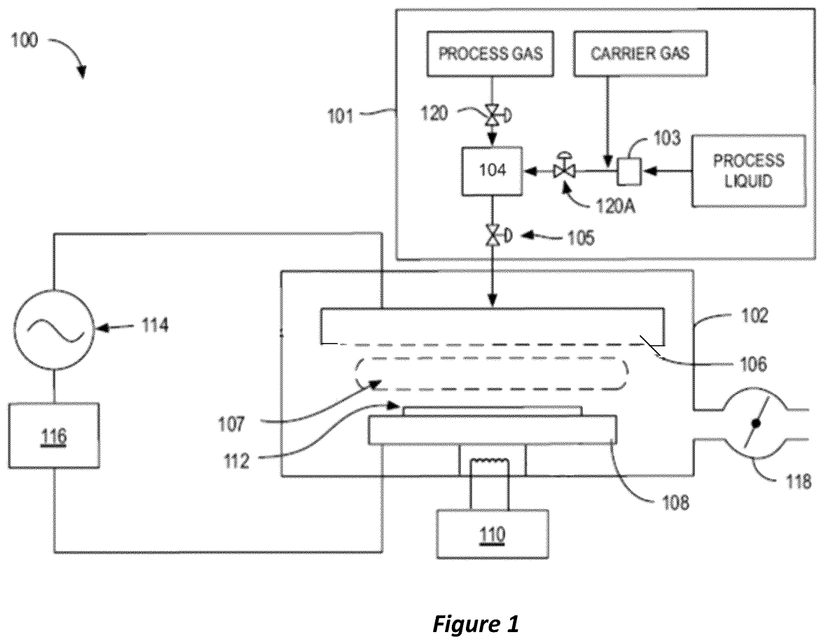

FIG. 1 shows a fabrication tool denoted as substrate processing apparatus 100. Apparatus 100 may be configured for depositing films on or over a semiconductor substrate utilizing any number of processes. For example, apparatus 100 may be adapted for performing, in particular, PECVD, ALD, or ALE.

Processing apparatus 100 of FIG. 1 may employ a single process station 102 of a process chamber with a single substrate holder 108 (e.g., a pedestal) in an interior volume, which may be maintained under vacuum by a vacuum pump 118. A showerhead 106 and a gas delivery system 101, which are fluidically coupled to the process chamber, may permit the delivery of film precursors, for example, as well as carrier and/or purge and/or process gases, secondary reactants, etc. It should be understood that the single station represented in FIG. 1 is merely one example, and, in some embodiments, the reactance control devices disclosed herein may be used in single stations, or in individual stations of a multi-station module.

In FIG. 1, gas delivery system 101 includes a mixing vessel 104 for blending and/or conditioning process gases for delivery to showerhead 106. One or more mixing vessel inlet valves 120 may control introduction of process gases to mixing vessel 104. Particular reactants may be stored in liquid form prior to vaporization and subsequent delivery to process station 102 of a process chamber. The implementation of FIG. 1 includes a vaporization point 103 for vaporizing liquid reactant to be supplied to mixing vessel 104. In some implementations, vaporization point 103 may include a heated liquid injection module. In some other implementations, vaporization point 103 may include a heated vaporizer. In yet other implementations, vaporization point 103 may be eliminated from the process station. In some implementations, a liquid flow controller upstream of vaporization point 103 may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead (e.g., valves 120, 120A, 105). In the implementation depicted in FIG. 1, substrate 112 is depicted as located beneath showerhead 106, and is shown resting on a pedestal 108. Showerhead 106 may include any suitable shape and may include any suitable number and arrangement of ports for distributing process gases to substrate 112. In some implementations involving two or more stations, gas delivery system 101 includes valves or other flow control structures upstream from the showerhead, which can independently control the flow of process gases and/or reactants to each station so as to permit gas flow to one station while prohibiting gas flow to a second station. Furthermore, gas delivery system 101 may be configured to independently control process gases and/or reactants delivered to each station in a multi-station apparatus such that the gas composition provided to different stations is different; e.g., the partial pressure of a gas component may vary between stations at the same time.

In the implementation of FIG. 1, plasma volume 107 is depicted as being located beneath showerhead 106. In some implementations, pedestal 108 may be raised or lowered to expose substrate 112 to plasma volume 107 and/or to vary the size of plasma volume 107. The separation between pedestal 108 and showerhead 106 is sometimes referred to as a “gap.” Optionally, pedestal 108 may be lowered and/or raised during portions of the deposition process to modulate process pressure, reactant concentration, etc., within plasma volume 107. Showerhead 106 and pedestal 108 are depicted as being electrically coupled to RF signal generator 114 and matching network 116 for coupling power to a plasma generator. Thus, showerhead 106 may function as an electrode for coupling radio frequency power into process station 102. RF signal generator 114 and matching network 116 may be operated at any suitable RF power level, which may operate to form plasma having a desired composition of radical species, ions, and electrons. In addition, RF signal generator 114 may provide RF power having more than one frequency component, such as a low-frequency component (e.g., less than about 2 MHz) as well as a high frequency component (e.g., greater than about 2 MHz). In some implementations, plasma ignition and maintenance conditions are controlled with appropriate hardware and/or appropriate machine-readable instructions in a system controller which may provide control instructions via a sequence of input/output control instructions.

As described above in connection with FIG. 1, a process station may include a showerhead and a pedestal, each of which may be considered electrodes. As described above, an RF signal may be applied to one of the electrodes, such as the pedestal. In such an example, the showerhead may be considered an unpowered electrode. An unpowered showerhead may still act as an inductor in the process station, where its inductance is generally referred to herein as L_{shd}. The showerhead inductance may generally be within a range of 10 nH-50 nH when unpowered. It is well known that inductive reactance (generally represented as X_{L}) is a subcomponent of impedance, which can be generally represented as Z. For simplicity, the relationship may be described as Z=R+jX, where Z is the impedance, R represents the resistance, j is the imaginary component and X is the reactance. When a circuit is built in series with an inductor, X can equal to X_{L}=2πfL=ωL, where f is the frequency measured in Hertz (Hz) and L is the inductance measured in Henries (H). Therefore, in a process station, increasing the inductance of the showerhead (powered or unpowered) L_{shd}. may increase the reactance (X) and impedance (Z) of the showerhead. When the RF signal is on and the resistance is insignificant (R=0), the impedance associated with the showerhead (generally referred to herein as Z_{shd}) can be determined from L_{shd} such that Z_{shd}=jωL_{shd}. Note that, because the showerhead's inductance does not contribute to resistance R, the impedance Z associated with the showerhead may be determined based on the inductive reactance X_{L} alone, which is tied to the inductance of the showerhead L_{shd}, for a given RF frequency. At relatively low RF frequencies, the effect of the showerhead inductance may have negligible effect on the impedance associated with the showerhead. Accordingly, the voltage across the showerhead may be negligible. In other words, at relatively low RF frequencies, the showerhead may effectively be DC grounded thereby having the same potential as the chamber. However, at higher RF frequencies (e.g., above 20 MHz, above 30 MHz, above 40 MHz, or the like), the impedance associated with the showerhead may increase, thereby causing a corresponding increase in the voltage across the showerhead (generally referred to herein as V_{shd}) relative to the chamber. It should be understood that in cases in which the RF signal is applied to the showerhead, the pedestal may be considered the unpowered electrode. Similar to what is described above with respect to a voltage developing across the showerhead at higher RF frequencies in instances in which the showerhead is the unpowered electrode, a voltage may develop across the pedestal in instances in which the pedestal is the unpowered electrode.

When the process station 102 is activated, the pedestal, the showerhead, and plasma generated between the pedestal and the showerhead may be represented as an equivalent circuit of resistors, inductors, and/or capacitors. In particular, the equivalent circuit may be a series RLC circuit. In an instance in which the pedestal is the powered electrode, the RLC circuit may include an inductor representing pedestal hardware that allows the RF signal generator to be electrically coupled to the pedestal, a capacitor and resistor in series representing plasma sustained between the pedestal and the showerhead, and an inductor representing the showerhead. As discussed above, a voltage across the showerhead (Vs_{hd}) may be affected by characteristics of an RF signal (e.g., RF signal frequency) applied to the pedestal. A voltage at a top portion of the pedestal (generally referred to herein as V_{ped}), corresponding to a surface of the pedestal on which a substrate undergoing processing is positioned, may also be affected by characteristics of the RF signal. Moreover, because the circuit elements are coupled in series, the voltage across the showerhead (V_{Shd}) may also impact the voltage at the top portion of the pedestal (V_{ped}). Accordingly, undesired voltage across the showerhead (e.g., due to the inductance of the showerhead) may cause undesired voltage changes at the surface of the pedestal, which may in turn cause undesired change in the plasma conditions within the process station. It should be understood that, as used herein, an undesired voltage may be a voltage across a component (e.g., a showerhead and/or a pedestal) that exceeds a voltage threshold. In some cases, the voltage threshold may be about 0 V. For example, such undesired voltages across various components in the station may cause parasitic plasma. As a more particular example, such parasitic plasma may include plasma between the showerhead and the wall, under a portion of the pedestal, or the like. Moreover, such undesired voltage changes may create undesirable fabrication effects on a wafer undergoing processing within the reactor, such as non-uniform deposition, non-uniform etching, or the like. It should be understood that in embodiments in which the powered electrode is the showerhead, and in which the unpowered electrode is the pedestal, the RF signal generator may be electrically coupled to an inductor representing the showerhead.

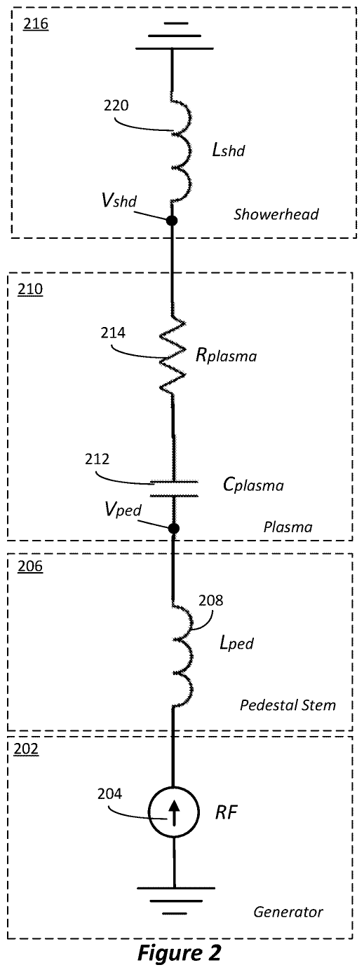

FIG. 2 shows a schematic diagram that illustrates components of a reactor that utilizes a pedestal as a powered electrode represented as equivalent circuit elements in accordance with some embodiments. As illustrated, an RF generator 202 is represented by a current source 204. As described above in connection with FIG. 1, RF signal generator 202 may be configured to provide RF signals at one or more frequencies, including a low frequency (e.g., about 2 MHz) and/or a high frequency (e.g., above 2 MHz). RF signal generator 202 is electrically coupled to a pedestal 206. The stem of the pedestal is represented by an inductor 208 (referred to as L_{ped}). As shown in FIG. 2, a voltage at a top portion of pedestal 206 is generally referred to herein as V_{ped}. A plasma 210, when present, is sustained between pedestal 206 and a showerhead 216. Plasma 210 may be represented by a capacitor 212 (generally referred to herein as Cₚₗₐₛₘₐ) and a resistor 214 (generally referred to herein as Rₚₗₐₛₘₐ), in series. In general, Rₚₗₐₛₘₐ represents a plasma slab resistance, and Cₚₗₐₛₘₐ represents a plasma sheath capacitance. Showerhead 216, when fixed to a wall of the reactor (as in conventional setups), is represented by an inductor 220 (referred to herein as L_{Shd}), which is in turn coupled to ground (i.e., the station wall). This configuration is sometimes referred to as a “grounded showerhead configuration.” The voltage across the showerhead, V_{Shd}, corresponds to the voltage at the node of the inductor 220 that is not grounded, as shown in FIG. 2.

In some embodiments, an reactance control device may be provided to a station of a processing chamber that effectively lowers the reactance (and therefore the impedance) associated with the showerhead. In particular, the reactance control device may be configured to be attached to a portion of the showerhead and to occupy a region or space between a top portion of the showerhead and a top wall of the station or a top plate of the showerhead. The reactance control device may be made of a conductive material such that RF signals can travel on a surface of the reactance control device. The reactance control device may be compliant with various chemical reactions that occur in the station. In some embodiments, the reactance control device may be made of aluminum or an aluminum alloy.

In some embodiments, an reactance control device may have an inner diameter corresponding to a portion of the reactance control device configured to receive a stem of the showerhead. The reactance control device may also have an outer diameter, where a bottom rim of the reactance control device has a diameter of the outer diameter. The bottom rim may be configured to rest on at least a portion of the top portion of the showerhead. In some embodiments, the reactance control device may be bolted and/or clamped to a portion of the showerhead. For example, the reactance control device may be clamped to the stem of the showerhead via a collar. Bolts and/or clamps used to attach the reactance control device to the showerhead may be made of a material having a relatively high tensile strength. For example, the bolts and/or clamps may be made substantially of stainless steel, Inconel, or the like.

In some embodiments, a bottom rim of the reactance control device may be configured to be in contact with the top portion of the showerhead. Note that, during performance of various process operations, the station may rise to relatively high temperatures, e.g., greater than 400 degrees Celsius, greater than 500 degrees Celsius, greater than 600 degrees Celsius, or the like. During processing, the reactance control device and/or portions of the showerhead may undergo thermal expansion due to the temperature increase. For example, during thermal expansion, the top portion of the showerhead may become convex, or bowed in a direction that causes the top portion of the showerhead to pull away from the bottom rim of the reactance control device. In some embodiments, the reactance control device may be bolted or clamped to a portion of the showerhead such that at least a portion of the bottom rim of the reactance control device remains in contact with the top portion of the showerhead when the reactance control device and/or the showerhead undergo thermal expansion. For example, in some embodiments, a range of about 40% to 60% of the bottom rim of the reactance control device may remain in contact with the top portion of the showerhead when the reactance control device and/or the showerhead undergo thermal expansion. As another example, in some embodiments, a range of about 45% to 55% of the bottom rim of the reactance control device may remain in contact with the top portion of the showerhead when the reactance control device and/or the showerhead undergo thermal expansion. In some embodiments, a portion of the bottom rim that is not in contact with any portion of the showerhead may be less than about 10 inches of the circumference of the bottom rim. In some embodiments, a portion of the bottom rim that is not in contact with any portion of the showerhead may be less than about 6 inches of the circumference of the bottom rim.

Note that, in some embodiments, the nominal inductance associated with the showerhead may be about 40 nH. Attachment of the reactance control device to the showerhead may cause the inductance to decrease to less than about 30 nH, less than about 20 nH, less than about 15 nH, or less than about 10 nH. Reduction of the inductance associated with the showerhead may decrease the reactance (and therefore the impedance) associated with the showerhead, which may in turn decrease a voltage across the showerhead when it is grounded. This may in turn decrease parasitic plasma, e.g., plasma in an undesired region of the station outside of a region between the bottom portion of the showerhead and a wafer being processed.

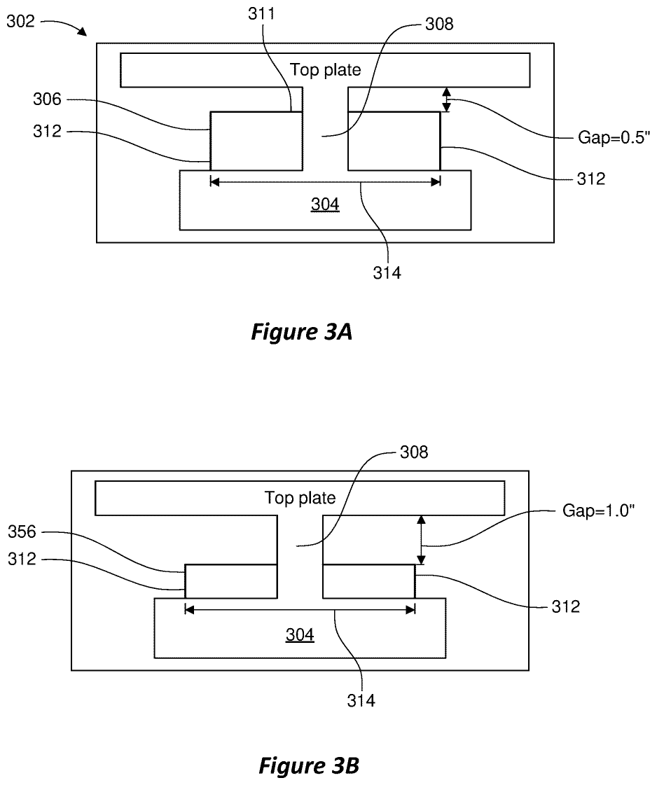

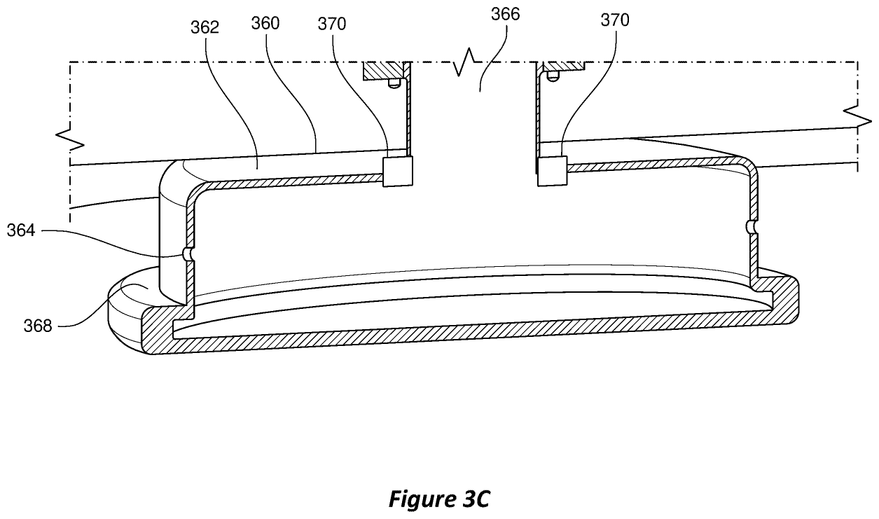

FIGS. 3A and 3B illustrate example configurations of reactance control device within a station of a process chamber. Note that FIGS. 3A and 3B illustrate cross-sectional side views of the station and the reactance control device. Referring to FIG. 3A, a station 302 includes a showerhead 304. The showerhead 304 has a stem 308. Reactance control device 306 is configured such that a bottom rim 312 of reactance control device 306 is in contact with a top surface of showerhead 304. As illustrated, reactance control device 306 includes an inner diameter through which stem 308 is configured to be positioned. Reactance control device 306 includes an outer diameter 314. Note that the bottom rim 312 of reactance control device 306 may have a substantially circular shape with a diameter corresponding to outer diameter 314. In the example shown in FIG. 3A, reactance control device 306 has a height such that there is a 0.5 inch gap between a top surface of reactance control device 306 and the top plate of the showerhead. Reactance control device 306 also includes an inner connective rim 311. At least a portion of the showerhead shaft may be configured to be positioned within inner connective rim 311, as shown in FIG. 3A.

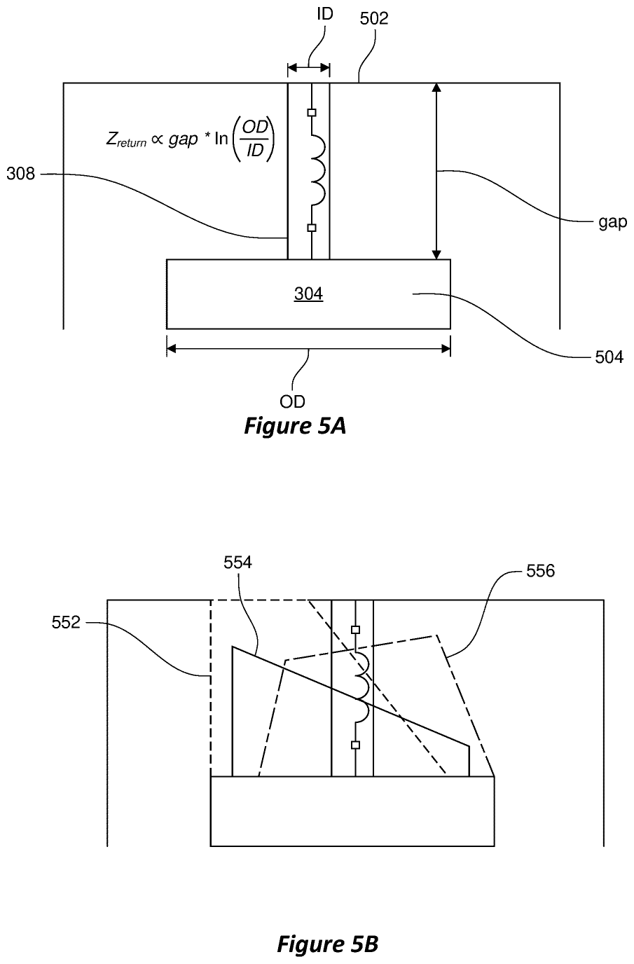

Referring to FIG. 3B, reactance control device 356 has the same inner diameter and outer diameter as reactance control device 306 of FIG. 3A. However, the height of reactance control device 356 differs from that of reactance control device 306 of FIG. 3A. In particular, the height of reactance control device 356 is smaller than the height of reactance control device 306, such that a gap between the top surface of reactance control device 356 and the top plate of the showerhead is 1 inch (e.g., twice as large as the gap between the top portion of reactance control device 306 and the top plate of the showerhead). Note that, as described below in connection with FIG. 5A, the impedance may be proportional to the gap, such that smaller gaps (e.g., that of the reactance control device shown in FIG. 3A) may be associated with a relatively lower inductance of the showerhead, and therefore a relatively lower impedance, relative to larger gaps between the top surface of the reactance control device and the top wall of the station or the top plate of the showerhead. It should be understood that the general form of inductance is the magnetic flux over the current. In instances in which the current travels through a looped wire, the magnetic flux may be reduced by reducing the cross-section area of the loop, which may be reduced, in the case of the wire, may be reduced by effectively stretching the wire straight. As mentioned above, reduction of the magnetic flux in turn reduces the inductance. A similar effect may be achieved by reducing the gap (i.e. cross sectional area of the horizontal space between the showerhead and the top plate) between the top plate of the showerhead and the station wall via the reactance control device.

Note that although FIGS. 3A and 3B illustrate reactance control devices having a side wall that is at substantially a 90 degree angle to the top wall, this is merely an example. In some implementations, a side wall of the reactance control device may be at greater than a 90 degree angle (e.g., 100 degrees, 120 degrees, 130 degrees, etc.) or less than 90 degrees (e.g., 85 degrees, 80 degrees, 60 degrees, etc.).

FIG. 3C illustrates a cross-sectional side view of an example reactance control device 360 in accordance with some embodiments. As illustrated, reactance control device 360 includes a top surface 362. Although top surface 362 is substantially flat in the example shown in FIG. 3C, in some examples, top surface 362 may be slanted, sloped, curved, etc. Additionally, although top surface 362 is depicted as having a uniform thickness, in some examples, top surface 362 may have varying thicknesses, e.g., increased or decreased thickness at the edges of top surface 362 relative to a middle portion of top surface 362. Reactance control device 360 also includes a side wall 364, which is a radially outward facing surface of reactance control device 360. Note that although side wall 364 is depicted as being about perpendicular to top surface 362, in some examples, side wall 364 may be at a non-right angle to top surface 362, e.g., 60 degrees, 70 degrees, 80 degrees, 100 degrees, 110 degrees, 120 degrees, etc. Although side wall 364 is depicted as having a uniform thickness, in some cases, thickness may vary across side wall 364. For example, a portion of side wall 364 that is closer to the top surface of the showerhead may have increased or decreased thickness relative to other portions of side wall 364.

Reactance control device 360 is attached to showerhead stem 366 via attachment points 370. In some examples, reactance control device 360 may have holes in, e.g., top surface 362 through which a mounting device (e.g., bolts and/or a collar) may be used to clamp reactance control device 360 to showerhead stem 366. A bottom rim of reactance control device 360 is configured to rest on a top surface 368 of the showerhead when reactance control device 360 is clamped to showerhead stem 366. Note that a portion of the bottom rim may remain in contact with top surface 368 of the showerhead even when reactance control device 360 and the showerhead undergo thermal expansion.

Note that, although top surface 360 and side wall 364 of reactance control device 360 are shown as being solid, in some cases, portions of top surface 360 and/or side wall 364 may be replaced by conductive metal bars, metal fence, and/or or a conductive metal mesh. Additionally, in some embodiments, different materials may be used for top surface 360 and side wall 364.

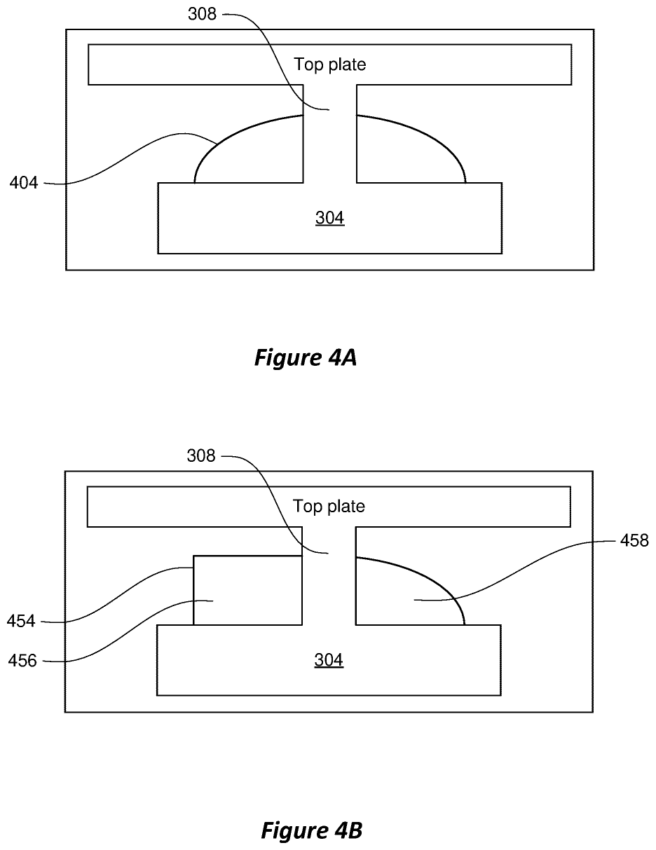

The reactance control devices shown in and described above in connection with FIGS. 3A, 3B, and 3C have a relatively flat top surface and are symmetric across an axis defined by the stem of the showerhead. However, in some embodiments, a reactance control device may have a sloped top surface. Additionally or alternatively, in some embodiments, a reactance control device may not be symmetric across the axis defined by the stem of the showerhead. FIG. 4A depicts an example reactance control device 404 having a sloped top surface. Note that although the sloped top surface of reactance control device 404 is curved, in some implementations, the top surface may have a sloped non-curved shape (e.g., as shown in FIG. 5B). FIG. 4B depicts an example reactance control device 454 having an asymmetric shape with respect to an axis defined by the stem of the showerhead. As illustrated, a first half 456 of reactance control device 454 has a substantially flat top surface, while a second half 458 has a sloped top surface.

As described above, the inductance associated with the showerhead, and therefore the reactance and/or impedance associated with the showerhead, may be proportional to a gap between a top surface of the showerhead and a top wall of the station and/or a top plate of the showerhead. By reducing the gap between the top surface of the showerhead and the top wall and/or the top plate by filling at least a portion of the gap with a reactance control device, the gap may be reduced, thereby reducing the inductance, reactance and/or impedance associated with the showerhead. The inductance, reactance, and/or impedance associated with the showerhead may also be proportional to a logarithm of a ratio of the inner diameter of the reactance control device to the outer diameter of the reactance control device. For example, the impedance may be represented as:

$${Z}_{return} ∝ gap * ln ( \frac{OD}{ID} )$$

In the equation given above, “OD” represents the outer diameter of the reactance control device (e.g., the outer diameter of the circle formed by the bottom rim of the reactance control device), and “ID” represents the inner diameter of the reactance control device configured to receive the stem of the showerhead. As illustrated by the above equation, the impedance associated with the showerhead (and relatedly, the reactance and/or the inductance associated with the showerhead) may be modified by modifying the shape, size, or dimensions of the reactance control device. For example, the impedance of the showerhead may be decreased by decreasing a gap between a top surface of the reactance control device and the top wall of the station or the top plate of the showerhead (e.g., by using a reactance control device with a taller height). As another example, the impedance of the showerhead may be decreased by decreasing a ratio of the outer diameter of the reactance control device to the inner diameter of the reactance control device.

FIG. 5A is a diagram that illustrates the various parameters of a reactance control device that may be tuned to modify an impedance associated with the showerhead. For example, FIG. 5A illustrates the gap between a top portion of showerhead 304 and a top wall 502 of the station. FIG. 5A also illustrates that the inner diameter of the reactance control device is defined by and/or limited by the diameter associated with the stem of the showerhead. For example, in some embodiments, the inner diameter of the reactance control device cannot be smaller than the diameter associated with the stem of the showerhead, because the inner diameter of the reactance control device is configured to receive the stem of the showerhead. As another example, the outer diameter of the reactance control device (e.g., the bottom rim of the reactance control device) is limited by the diameter associated with the showerhead, because the bottom rim of the reactance control device is configured to be in contact with the top portion of the showerhead.

FIG. 5B illustrates example reactance control devices having different shapes and sizes. For example, reactance control device 552 has a height and shape such that a gap between the top surface of reactance control device 552 is substantially larger for one half of reactance control device 552 compared to the other half of reactance control device 552. In other words, reactance control device 552 is asymmetric with respect to gap between the top surface of the reactance control device and the top wall of the station across the axis defined by the stem. Additionally, note that the top surface of reactance control device 552 is substantially flat for a portion of reactance control device 552, and is sloped for the remaining portion of reactance control device 552. A left side wall of reactance control device 552 that connects the top surface of reactance control device 552 to the bottom rim of reactance control device 552 has a substantially right angle.

Reactance control device 554, depicted in FIG. 5B is also asymmetric across the axis defined by the stem of the showerhead. The top surface of reactance control device 554 is sloped, and, due to the asymmetry of reactance control device 554, there is a larger gap at one side of reactance control device 554 than the other. The side walls that connect the top surface of reactance control device 554 to the bottom rim of reactance control device 554 are substantially right angles.

Reactance control device 556, depicted in FIG. 5C, is also asymmetric across the axis defined by the stem of the showerhead. The top surface of reactance control device 556 is sloped, and, due to the asymmetry of reactance control device 556, there is a larger gap at one side of reactance control device 556 relative to the other. The side walls that connect the top surface of reactance control device 556 to the bottom rim of reactance control device 556 are obtuse angles.

In some implementations, an reactance control device may be removably attached to the showerhead such that reactance control devices may be swapped or replaced. For example, a first reactance control device may be replaced by a second reactance control device in order to tune the inductance, reactance, and/or impedance associated with the showerhead, e.g., to meet particular process parameters. As a more particular example, a replacement reactance control device may have a size and/or a shape that modifies an inductance, reactance, and/or impedance of the showerhead toward a target value, where the target value may be dependent on a process to be performed within the station. Additionally, it should be noted that, in some embodiments, asymmetries of an reactance control device, or other physical characteristics of the reactance control device, may be used to compensate for asymmetries across stations of a multi-station chamber. For example, each station may utilize a differently shaped reactance control device that is selected for the properties of the showerhead in the station, and that allows the inductance, reactance, and/or impedance of the showerhead in the station to compensate for asymmetries due to the other stations in the multi-station chamber.

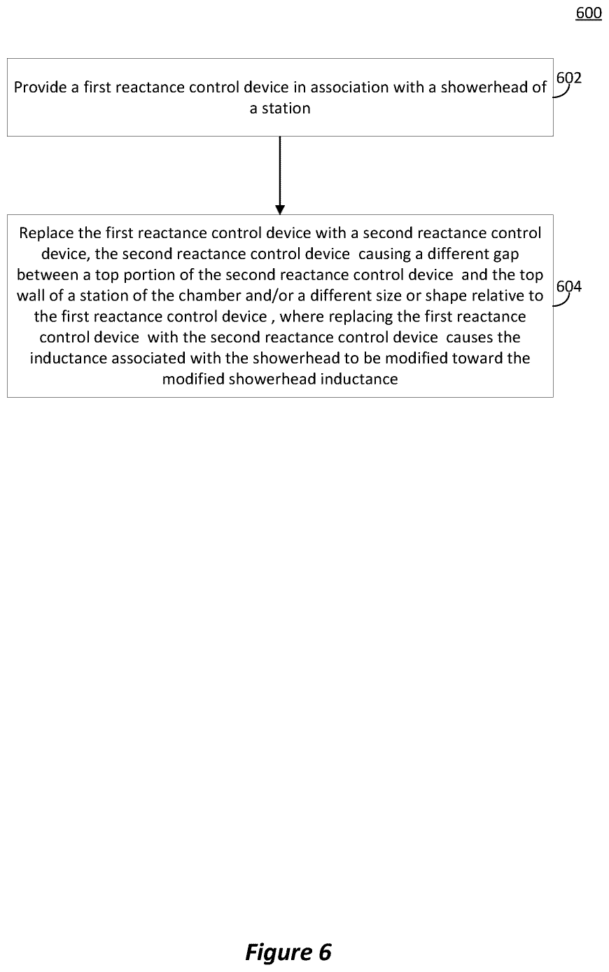

FIG. 6 is a flowchart of an example process 600 for replacing a first reactance control device with a second reactance control device in accordance with some embodiments. Process 600 may be performed responsive to selection of a design for a reactance control device to be utilized in a given station for a given process.

Process 600 can begin at 602 by providing a first reactance control device in association with a showerhead of a station. The first reactance control device may have first physical properties, such as an asymmetry of the reactance control device across an axis defined by the stem of the showerhead, a height that relates to a gap between a top surface of the reactance control device and a top wall of the station or a top plate of the showerhead, a shape of the top surface (e.g., whether the top surface is flat, sloped in a curved manner, sloped in a non-curved manner, etc.), or the like.

At 604, the first reactance control device may be replaced with a second reactance control device, the second reactance control device causing a different gap between a top portion of the second reactance control device and a top wall of the station of the chamber and/or a different size or shape relative to the first reactance control device. Replacement of the first reactance control device with the second reactance control device may cause the inductance associated with the showerhead to be modified toward the modified showerhead inductance. Note that, in some embodiments, the second reactance control device may be identified or selected based on a determination that a process being performed in the station is to be adjusted at least by adjusting an inductance associated with the showerhead toward a modified showerhead inductance may be made. Note that, because of the relationship between inductance, reactance, and impedance, adjusting the inductance of the showerhead also adjusts the reactance and the impedance associated with the showerhead. The modified showerhead inductance may be determined based on empirical data indicating an amount or locations of parasitic plasma within the station, and/or any other suitable empirical data. For example, the modified showerhead inductance may be lower than or greater than the current inductance associated with the showerhead. Note that, in some embodiments, process 600 may be looped such that the second reactance control device is replaced with a third reactance control device, etc. This may allow for iterative convergence to an reactance control device that causes the inductance of the showerhead to be optimal for a process to be performed in the station.

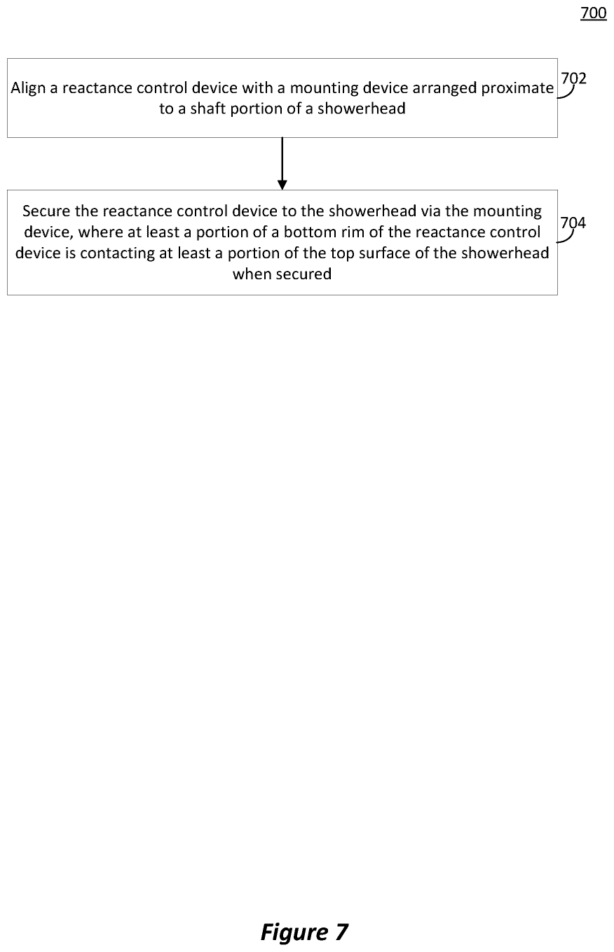

FIG. 7 is a flowchart of an example process 700 for installing a reactance control device in accordance with some embodiments. Process 700 may be performed by an installer of the reactance control device who, e.g., installs the reactance control device in a given station. The process of installation may involve clamping or otherwise securing the reactance control device to a portion of a shaft of the showerhead, ensuring that at least a portion of the bottom rim of the reactance control device is in contact with a top surface of the showerhead, etc. Note that a reactance control device may be installed (e.g., affixed) to a showerhead of a station prior to installation of the showerhead within a tool.

Process 700 can begin at 702 by aligning a reactance control device with a mounting device arranged proximate to a shaft portion of a showerhead. As described above, the reactance control device may include a bottom rim configured to contact at least a portion of a top surface of a showerhead. The reactance control device may include a body surface with an inner connective rim and an outer perimeter connected to the bottom rim via a side wall. The diameter of the inner connective rim may be smaller than the outer perimeter of the body surface. The inner connective rim may define a through hole which may be configured to accommodate a portion of a shaft of the showerhead. Accordingly, the aligning the reactance control device may involve aligning the through hole with respect to the shaft of the showerhead.

At 704, process 700 can secure the reactance control device to the showerhead via the mounting device. Upon securing the reactance control device, at least a portion of the bottom rim perimeter of the reactance control device (e.g., at least about 40% to 60% of the bottom rim perimeter, at least about 45% to 55% of the bottom rim perimeter, at least about 50% of the bottom rim perimeter, etc.) may be configured to be in contact with the top surface of the showerhead. The mounting device may include a collar, one or more bolts, etc., as described above.

Note that process 700 may be repeated for multiple stations, e.g., multiple stations of a multi-station module or process chamber.

### CONCLUSION

In the description, numerous specific details were set forth in order to provide a thorough understanding of the presented embodiments. The disclosed embodiments may be practiced without some or all of these specific details. In other instances, well-known process operations were not described in detail to not unnecessarily obscure the disclosed embodiments. While the disclosed embodiments were described in conjunction with the specific embodiments, it will be understood that the specific embodiments are not intended to limit the disclosed embodiments.

Unless otherwise indicated, the method operations and device features disclosed herein involves techniques and apparatus commonly used in metrology, semiconductor device fabrication technology, software design and programming, and statistics, which are within the skill of the art.

Unless defined otherwise herein, all technical and scientific terms used herein have the same meaning as commonly understood by one of ordinary skill in the art. Various scientific dictionaries that include the terms included herein are well known and available to those in the art. Although any methods and materials similar or equivalent to those described herein find use in the practice or testing of the embodiments disclosed herein, some methods and materials are described.

Numeric ranges are inclusive of the numbers defining the range. It is intended that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

The headings provided herein are not intended to limit the disclosure.

As used herein, the singular terms “a.” “an,” and “the” include the plural reference unless the context clearly indicates otherwise. The term “or” as used herein, refers to a non-exclusive or, unless otherwise indicated.

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware—for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

1. A reactance control device for a showerhead in a processing chamber, the reactance control device comprising:
a bottom rim configured to contact at least a portion of a top surface of a showerhead;
a body surface with an inner connective rim and an outer perimeter connected to the bottom rim via a side wall, a diameter of the inner connective rim is smaller than the outer perimeter of the body surface,
wherein the inner connective rim defines a through hole configured to accommodate a portion of a shaft of the showerhead, and the inner connective rim is further configured to engage a mounting device arranged approximate to the shaft portion of the showerhead in order to secure the reactance control device to the showerhead.

2. The reactance control device of claim 1, wherein the body surface is configured to fill at least a portion of a station of the processing chamber between the top surface of the showerhead and a top wall of the station, the body surface comprising a conductive material and configured to support electromagnetic coupling when the showerhead is powered by an RF source.

3. The reactance control device of claim 2, wherein the side wall defines a height of the reactance control device, and the height of the reactance control device is less than a distance between the top surface of the showerhead and the top wall of the station.

4. The reactance control device of claim 1, comprising one or more subparts and each of the one or more subparts defines a portion of the inner connective rim.

5. The reactance control device of claim 1, wherein a top portion of the body surface is flat.

6. The reactance control device of claim 1, wherein a top portion of the body surface is at least partially sloped.

7. The reactance control device of claim 1, wherein the body surface forms a convex shape, and wherein an inner region formed by the convex shape is not filled.

8. The reactance control device of claim 1, wherein the body surface comprises a conductive material, and wherein the conductive material comprises Aluminum.

9. The reactance control device of claim 1, wherein a perimeter of the bottom rim is within a range of about 30 inches to 50 inches.

10. The reactance control device of claim 1, wherein a range of about 40% to 60% of the bottom rim is configured to remain in contact with the at least the portion of the top surface of the showerhead when the reactance control device undergoes thermal expansion.

11. The reactance control device of claim 1, wherein the mounting device is a collar configured to clamp the reactance control device.

12. The reactance control device of claim 11, wherein the collar is made of a material that comprises Inconel.

13. The reactance control device of claim 1, wherein the reactance control device is configured to reduce an inductance associated with the showerhead by at least about half relative to the inductance associated with the showerhead when not in contact with the reactance control device.

14. The reactance control device of claim 1, wherein the reactance control device is configured to reduce an inductance associated with the showerhead to less than about 30 nH.

15. A showerhead apparatus, comprising:
a showerhead; and
a reactance control device connected to a portion of a shaft of the showerhead, the reactance control device comprising:
a bottom rim configured to contact at least a portion of a top surface of the showerhead, and
a body surface with an inner connective rim and an outer perimeter connected to the bottom rim via a side wall, a diameter of the inner connective rim is smaller than the outer perimeter of the body surface,
wherein the inner connective rim defines a through hole configured to accommodate a portion of a shaft of the showerhead, and the inner connective rim is further configured to engage a mounting device arranged approximate to the shaft portion of the showerhead in order to secure the reactance control device to the showerhead.

16. The showerhead apparatus of claim 15, wherein the reactance control device is clamped to the showerhead.

17. The showerhead apparatus of claim 15, wherein a top portion of the body surface is flat.

18. The showerhead apparatus of claim 15, wherein a top portion of the body surface is at least partially sloped.

19. The showerhead apparatus of claim 15, wherein the body surface forms a convex shape, and wherein an inner region formed by the convex shape is not filled.

20. The showerhead apparatus of claim 15, wherein the body surface comprises a conductive material, and wherein the conductive material comprises Aluminum.

21.-27. (canceled)
